(19) United States
(12) Patent Application Publication
(10) Pub. No.: US 2015/0371825 A1
(43) Pub. Date: Dec. 24, 2015

(54) PLASMA PROCESSING APPARATUS

(71) Applicant: Hitachi High-Technologies Corporation, Tokyo (JP)

(72) Inventors: Hiroyuki Kobayashi, Tokyo (JP); Makoto Nawata, Tokyo (JP); Hikaru Koyama, Tokyo (JP); Kazuyuki Ikenaga, Tokyo (JP)

(73) Assignee: HITACHI HIGH-TECHNOLOGIES CORPORATION

(21) Appl. No.: 14/627,022

(22) Filed: Feb. 20, 2015

(30) Foreign Application Priority Data
Jun. 23, 2014 (JP) 2014-128197

(51) Int. Cl. H01J 37/32; C23C 16/44; C23C 16/455; C23C 16/50

(52) U.S. Cl. CPC H01J 37/3244; C23C 16/50; C23C 16/4412; C23C 16/45565; H01J 37/32009

(57) ABSTRACT

A plasma processing apparatus in which high frequency power to generate plasma supplied from a high frequency power supply is introduced into a processing chamber via a top plate and a shower plate and a member to be processed mounted on a stage electrode is processed, wherein a grounded spacer whose base material is a metal is installed between the shower. plate and an inner cylinder.

### BACKGROUND OF THE INVENTION

The present invention relates to a plasma processing apparatus.

Plasma etching is widely used in fabrication processes of semiconductor devices such as DRAM and microprocessors. As one of challenges in processing of semiconductor devices using plasma, reducing the amount of metallic elements adhering to a wafer (reducing metallic contamination) can be cited. If, for example, devices are fabricated while metallic atoms of iron, aluminum or the like adhere to the wafer, degradation of device characteristics may be caused, leading to lower yields. Thus, materials containing less metal are increasingly used as materials used for inner walls of a processing chamber or materials of less consumption (plasma resistant materials) are adopted. As an example of adopting materials containing less metal as materials used for inner walls of a processing chamber, providing of a quartz cover on the surface of inner walls of the processing chamber and structures inside the processing chamber so that most of inner walls in contact with plasma is the quartz can be cited (for example, JP-A-2001-217225 and JP-A-2008-251857 (corresponding to U.S. Patent Publication No. 2008/236494)).

### SUMMARY OF THE INVENTION

With increasingly microscopic structures of devices, requirements for the reduction of metallic contamination become more severe. Thus, the inventors examined possible locations of the source of metallic contamination in a plasma processing apparatus. The examination result will be described below by taking a μ wave-ECR plasma etching apparatus as an example.

In a plasma processing apparatus such as a μ wave-ECR plasma etching apparatus configured to introduce high frequency power for plasma generation and bias power into a processing chamber through the window of a dielectric material, a cover (inner cylinder) of quartz or ceramic such as yttria is installed to prevent bulk plasma (plasma with which to perform plasma processing on a member to be processed) from coming into contact with inner walls or components that could become a source of metallic contamination. When configured as described above, if the inner cylinder is installed close to the window of the dielectric material within a fixed distance therefrom, it turns out that high frequency power for plasma generation is more likely to propagate into the inner cylinder and separately from bulk plasma generated to perform plasma processing on the member to be processed, a local discharge (abnormal discharge) arises between the inner cylinder and the inner wall or various components to be protected in the inner cylinder. Due to the local discharge, there is a concern of contamination of wafer after metallic elements generated from the surface of the inner wall or components being mixed into the bulk plasma. Therefore, it is necessary to suppress the discharge arising in such a gap and also to take measures to suppress the propagation of the high frequency power.

JP-A-2008-251857 discloses that a conductive material is installed inside a cover of a sidewall made of quartz. According to this method, however, a conductor is potentially floating and high frequency power is considered to be propagated by excitation of the conductor. In addition, the high frequency power propagates near the surface of the quartz without going through a conductive material inside the quartz and therefore, blocking the propagation of the high frequency power adequately is determined to be difficult.

An object of the present invention is to provide a plasma processing apparatus capable of reducing metallic contamination of a member to be processed during plasma processing.

As an embodiment to achieve the object, a plasma processing apparatus having a processing chamber; a gas supply unit that supplies a process gas to the processing chamber; an exhaust unit that reduces a pressure of the processing chamber; a high frequency power supply to supply high frequency power that generates plasma inside the processing chamber; a stage electrode arranged in the processing chamber to mount a member to be processed on; a high frequency bias power supply that applies a high frequency bias to accelerate ions incident on the member to be processed to the stage electrode; a top plate installed in an upper portion of the processing chamber; a shower plate installed below the top plate to supply the process gas into the processing chamber; and an inner cylinder arranged below the shower plate to prevent a sidewall of the processing chamber from coming into direct contact with plasma and in which the high frequency power to generate the plasma is introduced into the processing chamber via the top plate and the shower plate, wherein

a grounded spacer whose base material is a metal is installed between the shower plate and the inner cylinder.

Also, a plasma processing apparatus includes:

a grounded chamber;

a processing chamber arranged inside the chamber to process a member to be processed by using plasma;

a gas supply unit that supplies a process gas to the processing chamber;

an exhaust unit that reduces a pressure of the processing chamber; a high frequency power supply that supplies high frequency power to generate the plasma;

a stage electrode arranged in the processing chamber to mount the member to be processed on;

a high frequency bias power supply that applies a high frequency bias to accelerate ions incident on the member to be processed to the stage electrode;

a shower plate installed in an upper portion of the processing chamber to supply the process gas into the processing chamber;

an inner cylinder arranged below the shower plate to prevent a sidewall of the chamber from coming into direct contact with the plasma;

a ground arranged to cover a portion of the inner cylinder via a gap and whose surface on a center side of the processing chamber is coated with a plasma resistant material; and

a spacer arranged between the shower plate and the inner cylinder by being grounded, whose surface on the center side of the processing chamber is coated with the plasma resistant material and whose base material is a conductor.

According to the present invention, by arranging a grounded spacer between a shower plate and an inner cylinder, the propagation of high frequency power from the shower plate into the inner cylinder made of a dielectric material such as quartz is blocked, generation of local plasma in a gap between the inner cylinder and a wall surface opposed to the inner cylinder is suppressed, and generation of metallic elements causing metallic contamination from the wall surface in the gap is suppressed and therefore, a plasma processing apparatus capable of reducing metallic contamination of a member to be processed during plasma processing can be provided

Other objects, features and advantages of the invention will become apparent from the following description of the embodiments of the invention taken in conjunction with the accompanying drawings.

### BRIEF DESCRIPTION OF THE DRAWINGS

FIG. 1 is a schematic sectional view of a plasma processing apparatus according to a first embodiment of the present invention;

FIG. 2 is a principal portion sectional view illustrating problems of a plasma processing apparatus of related art;

FIG. 3 is a principal portion sectional view of the plasma processing apparatus according to the first embodiment of the present invention;

FIG. 4 is a principal portion sectional view of the plasma processing apparatus according to a second embodiment of the present invention;

FIG. 5 is a principal portion sectional view illustrating problems when a ring-shaped spacer is not grounded in the plasma processing apparatus according to the first embodiment of the present invention; and

FIG. 6 is a principal portion sectional view illustrating a detailed configuration of the plasma processing apparatus according to the first embodiment of the present invention.

### DESCRIPTION OF THE EMBODIMENTS

The embodiments of the present invention will be described below with reference to the drawings. A μ wave-ECR plasma etching apparatus will mainly be described in the embodiments, but the present invention can also be applied to other plasma processing apparatuses. In figures, the same reference numeral indicates the same component.

### First Embodiment

The first embodiment of the present invention will be described with reference to the drawings.

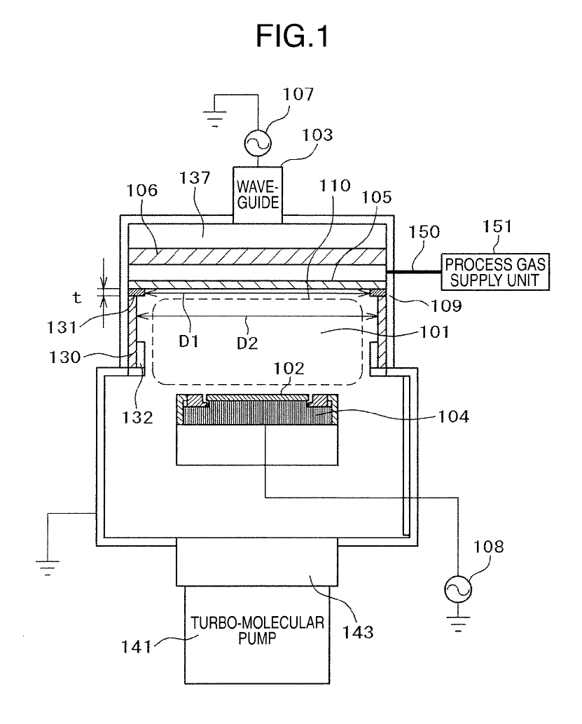

FIG. 1 is a schematic sectional view of a μ wave-ECR plasma etching apparatus as a representative configuration example of a plasma processing apparatus according to the present embodiment. A micro wave to generate plasma is transmitted to a cavity resonator 137 through a waveguide 103 and introduced into a processing chamber 101 via a quartz top plate 106 and a shower plate 105 installed in an upper portion of a grounded chamber 109. Incidentally, reference numeral 107 is a high frequency power supply to supply high frequency power (micro wave) for generating plasma. A process gas is supplied from a process gas supply unit 151 to a space between the shower plate 105 and the top plate 106 via a gas supply line 150 and introduced into the processing chamber 101 via a gas hole (not shown) provided in the shower plate 105. A stage electrode 104 to mount a member to be processed (wafer) 102 on is installed below the shower plate 105 and opposite to the shower plate 105 and connected to a high frequency bias power supply 108 to apply a high frequency bias to the wafer 102 via the stage electrode 104. A turbo-molecular pump 141 is mounted via a pressure control valve unit 143 below the chamber 109 as an exhaust unit to reduce the pressure in the processing chamber 101 and also to exhaust a supplied process gas. Though not shown, a magnetic coil to form a magnetic field around the chamber 109 and a power supply for electrostatic chuck to cause the stage electrode 104 to electrically chuck the wafer 102 are installed.

An inner cylinder (sidewall cover) 130 is installed in a sidewall portion forming a space above the wafer 102 in the processing chamber 101 In the present embodiment, quartz is selected as the material of the inner cylinder. A ground 132 is installed in a lower portion of the inner cylinder 130. The member constituting the ground 132 is a metal such as aluminum whose surface is coated with yttria.

A ring-shaped spacer 131 is installed between the inner cylinder 130 and the shower plate 105. The ring-shaped spacer 131 uses aluminum as a base material and the entire surface on the inner side of the ring-shaped spacer (center side of the processing chamber) and portions of a top surface and a bottom surface are coated with yttria as a plasma resistant material. Then, electric conduction to the chamber 109 is realized through a portion not coated with yttria. An inside diameter D1 of the ring-shaped spacer 131 is set smaller than an inside diameter D2 of the inner cylinder 130. While a local discharge can be suppressed by arranging the ring-shaped spacer 131 between the shower plate 105 and the inner cylinder 130, the local discharge can be suppressed more effectively by adopting the above relationship between the inside diameter D1 and the inside diameter D2 (details will be described later). The plane shape of the ring-shaped spacer is adjusted to the shape when the inner cylinder is viewed vertically from above and if the shape when the inner cylinder is viewed vertically from above is not a ring shape, the plane shape is changed accordingly. A metal is used as a base material in the embodiments, but any conductor may be used. However, metals of low resistance are desirable.

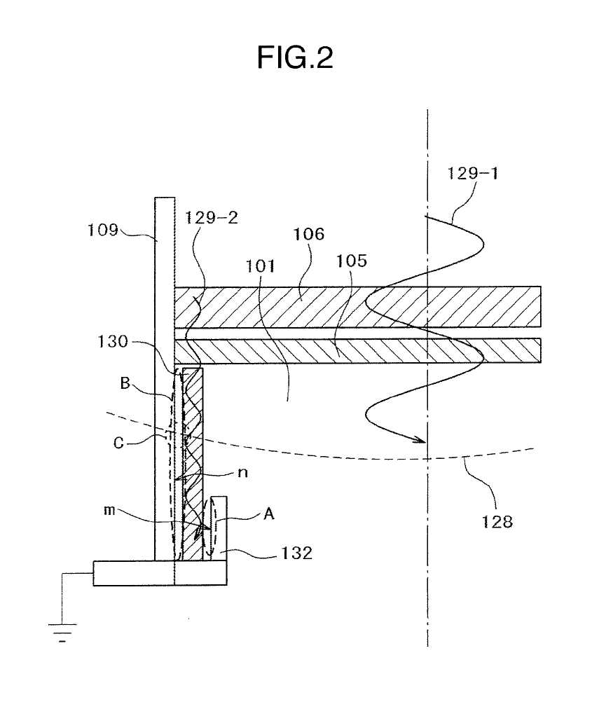

Next, problems of a plasma processing apparatus of related art will be described with reference to FIG. 2. FIG. 2 shows a state of the propagation of a micro wave when no ring-shaped spacer is installed. A micro wave 129-1 to generate plasma is introduced into the processing chamber 101 via the quartz top plate 106 and the quartz shower plate 105. The micro wave 129-1 having been transmitted to the quartz shower plate 105 attempts to be propagated to the neighboring quartz (material having almost the same dielectric constant). Thus, a portion 129-2 of the micro wave 129-1 propagates through the inner cylinder 130. The micro wave 129-2 having propagated to the inner cylinder 130 can generate plasma on the surface of the inner cylinder 130. The inner cylinder 130 needs to be removed for replacement/cleaning of various parts during maintenance and thus, fixed gaps (A, B respectively) are secured between the inner cylinder 130 and the chamber 109 and between the inner cylinder 130 and the ground 132. Therefore, plasma is locally generated in these gaps by the micro wave 129-2 (local discharge). In addition, strong plasma may be generated in a neighborhood C of an ECR surface 128 (the magnetic field strength is 0.0875 T when the frequency of the micro wave is 2.45 GHz).

The surface (surface m on the backside) of the ground 132 in the gap A and a surface n of the chamber 109 in the gap B are not directly visible to bulk plasma (there is no incidence of ions generated in the bulk plasma). Thus, these surfaces are not coated with yttria or the like, which has strong plasma resistance, hut is expensive. Therefore, such surfaces are SUS, aluminum, or alumite and if plasma is generated in the gap A or B, metallic elements may be generated and mixed into the bulk plasma to cause metallic contamination of the wafer (in this case, a metal generated by discharge in the gap B is mixed into the bulk plasma via, for example, a gap formed between the shower plate 105 and the inner cylinder 130).

In contrast, by installing the ring-shaped spacer 131 between the quartz shower plate 105 and the inner cylinder 130 as shown in FIG. 1, a micro wave can be prevented from propagating into the inner cylinder 130, Accordingly, a local discharge in the gaps A, B can be suppressed.

Next, the material and thickness of the ring-shaped spacer will be described. If the base material of the ring-shaped spacer is a metal, the depth to which the surface effect of a current extends may be considered to determine whether a micro wave can be blocked. If the angular frequency (value obtained by multiplying the frequency Hz by 2ρ) of the micro wave is ω, the magnetic permeability is μ, and the conductivity is σ, the depth δ of the surface effect is given by

δ=(2/(ω·μ·σ))^{0.5}

Therefore, the thickness of the metal as the base material of the ring-shaped spacer is desirably made thicker than the depth to which the surface effect of extends and if the thickness of the metal as the base material of the ring-shaped spacer in a position between the shower plate and the inner cylinder is t, it is desirable to set

t≧δ

that is,

t≧(2/(ω·μ·σ))^{0.5}

If the frequency of the micro wave is 2.45 GHz and the base material is aluminum, the depth of the surface effect is on the order of 1 μm. In the present embodiment, the thickness t is set to a few mm from the viewpoint of difficulty of actual processing.

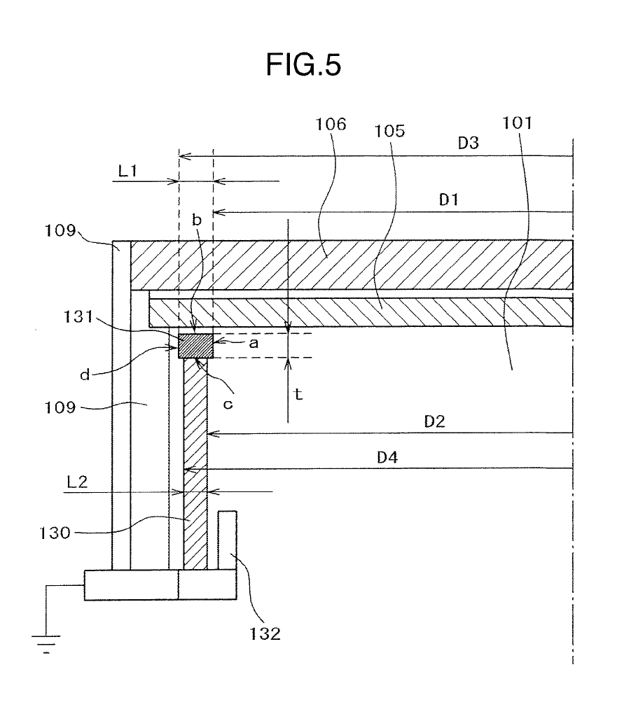

Next, the significance of grounding the ring-shaped spacer will be described. FIG. 5 shows a case when the ring-shaped spacer 131 is not electrically in contact with the chamber 109 or the like in the plasma processing apparatus according to the present embodiment. The ring-shaped spacer 131 is a ring-shaped component using aluminum as its base material and surfaces a, b, c, d are all coated with yttria. A width L1 of the ring-shaped spacer 131 is larger than a width L2 of the inner cylinder 130. In addition, the inside diameter D1 of the ring-shaped spacer 131 is smaller than the inside diameter D2 of the inner cylinder and an outside diameter D3 of the ring-shaped spacer 131 is larger than an outside diameter D4 of the inner cylinder 130 or almost the same (being almost the same is a case when the gap A between the inner cylinder and the chamber 109 is very narrow). Then, the ring-shaped spacer 131 is installed like being put on atop end of the inner cylinder 130. In this configuration, it is difficult to sufficiently inhibit a micro wave having reached the shower plate 105 from propagating to the inner cylinder 130. Further, the ring-shaped spacer 131 allows a portion of the micro wave to propagate to the inner cylinder 130 by excitation. Therefore, it is desirable to electrically bring the ring-shaped spacer 131 into contact with the chamber 109 or the like acting as a ground to prevent excitation of the ring-shaped spacer 131.

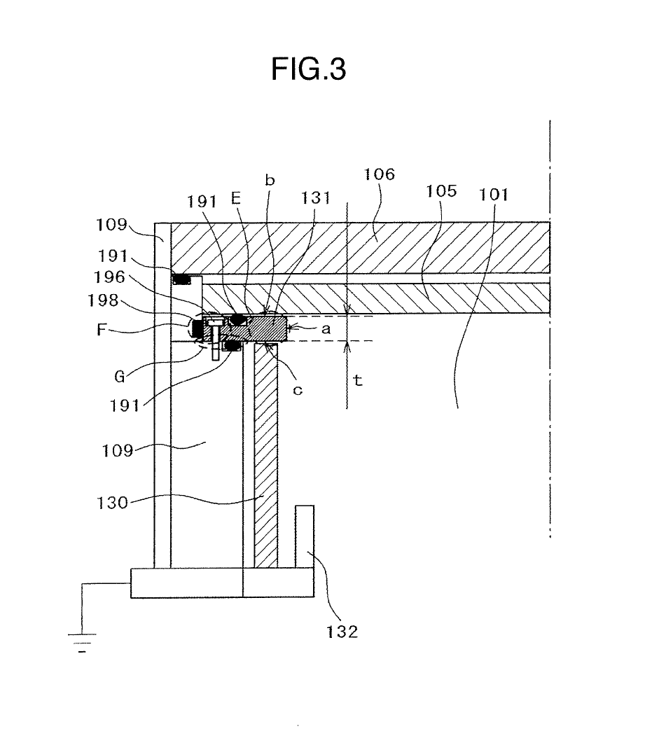

Next, a desirable structure of the ring-shaped spacer will be shown more concretely. FIG. 3 is a principal portion sectional view of the plasma processing apparatus according to the present embodiment and shows a configuration example in which the ring-shaped spacer 131 is removable from other parts. The ring-shaped spacer 131 is to be put on a step surface G of the chamber 109. Then, the shower plate 105 is to be put thereon. An O-ring 191 is installed between the ring-shaped spacer 131 and the chamber 109 and between the ring-shaped spacer 131 and the shower plate 105. A surface a on the inner side of the ring-shaped spacer 131 is coated with yttria and also the neighborhood of a region E close to bulk plasma of a top surface b and a bottom surface c is coated with yttria. On the other hand, a portion (near a region F) where the ring-shaped spacer 131 comes into contact with the chamber 109 is not coated with an insulating material to allow conduction. To realize conduction reliably, a spiral seal 198 is installed between the ring-shaped spacer 131 and the chamber 109. Further, the ring-shaped spacer 131 is to be fixed to the chamber 109 by a bolt 196.

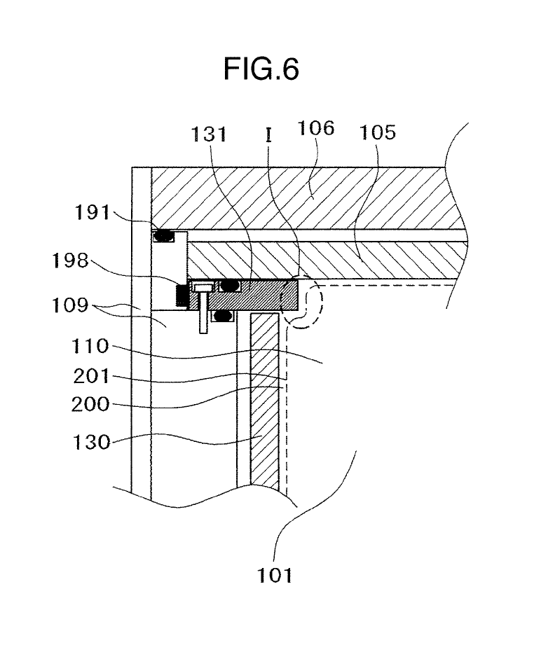

Next, the reason why the inside diameter D1 of the surface a on the inner side of the ring-shaped spacer is smaller than the inner cylinder D2 will be described with reference to FIG. 6. FIG. 6 is a principal portion sectional view to illustrate a detailed configuration of the plasma processing apparatus according to the present embodiment and shows the neighborhood of the ring-shaped spacer in FIG. 3 after the neighborhood being enlarged. Bulk plasma 110 to perform plasma processing on a member to be processed is generated inside the processing chamber 101. Then, a sheath 200 is generated near the wall surface of the inner cylinder 130 and the shower plate 105. While it is difficult for a micro wave to propagate in the bulk plasma, a certain level of micro wave can propagate inside the sheath 200 due to a lower electron density. However, as shown in FIGS. 1 and 6, if the inside diameter D1 of the ring-shaped spacer 131 is made smaller than the inside diameter D2 of the inner cylinder, a boundary 201 between the sheath 200 and the bulk plasma 110 is, as shown in a region I, not linear, but has a crank shape by being formed along the wall surface. Because a micro wave is less likely to pass if the waveguide has a crank shape, a micro wave propagating up to the inner cylinder 130 by going through the sheath near the region I can be reduced compared with a case when the inside diameter D1 of the ring-shaped spacer 131 and the inside diameter D2 of the inner cylinder 130 are almost the same. Therefore, the inside diameter D1 of the ring-shaped spacer 131 is desirably twice the thickness of the sheath near the ring-shaped spacer 131 or more and smaller than the inside diameter D2 of the inner cylinder. That is, the propagation of a micro wave from the shower plate 105 to the inner cylinder can be suppressed by arranging the ring-shaped spacer 131 between the shower plate 105 and the inner cylinder 130 and therefore, a local discharge can be suppressed and also a micro wave propagating up to the inner cylinder 130 by going through the sheath 200 can further be reduced by making the inside diameter D1 of the ring-shaped spacer 131 smaller than the inside diameter D2 of the inner cylinder 130 so that a local discharge can be suppressed more effectively.

As a result of applying the configuration shown in FIG. 3 to the plasma processing apparatus shown in FIG. 1 and applying the apparatus to plasma processing of semiconductor devices, by arranging a grounded spacer between a shower plate and an inner cylinder, the propagation of high frequency power from the shower plate into the inner cylinder made of a dielectric material such as quartz is blocked, generation of local plasma in a gap between the inner cylinder and a wall surface opposed to the inner cylinder is suppressed, and generation of metallic elements causing metallic contamination from the wall surface in the gap is suppressed and therefore, metallic contamination of a member to be processed during plasma processing can be reduced.

In the present embodiment, quartz is used for the shower plate and the inner cylinder. However, the quartz material of the inner cylinder and the shower plate can also be constituted of other dielectric materials, for example, a sintered yttria material. In addition, materials of slightly different dielectric constants can be combined such as both of the shower plate and the inner cylinder are yttria and one is yttria and the other is quartz.

When the ring-shaped spacer 131 is made of, instead of metal, dielectric materials totally including the base material, if the wavelength of high frequency power inside the ring-shaped spacer is λ′, a certain degree of shielding effect can be expected by setting a thickness that does not allow the following formula to hold true if possible:

t=0.5nλ′.

In addition, metallic contamination can further be reduced by coating the backside (surface m in FIG. 2) of the ground on the side on which the inner cylinder is installed and the wall surface (surface n in FIG. 2) protected by the inner cylinder with yttria or the like having strong plasma resistance.

According to the present embodiment, as described above, a plasma processing apparatus capable of reducing metallic contamination of a member to be processed during plasma processing can be provided. In addition, a micro wave propagating up to the inner cylinder by going through the sheath can further be reduced by making the inside diameter D1 of the ring-shaped spacer smaller than the inside diameter D2 of the inner cylinder so that a local discharge can be suppressed more effectively.

### Second Embodiment

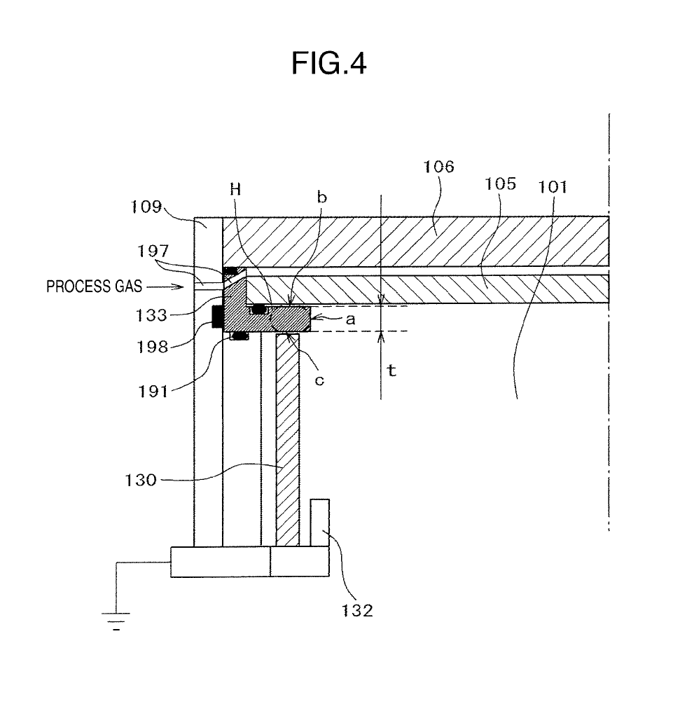

The second embodiment of the present invention will be described using FIG. 4. If not specifically specified, items that are described in the first embodiment and are not described in the present embodiment can also be applied to the present embodiment.

FIG. 4 is a principal portion sectional view of the plasma processing apparatus according to the second embodiment of the present invention and is different from FIG. 3 in that a function as a ring-shaped spacer is added to ahead piece 133 (component having a function (channel 197 of gases) that supplies a process gas to between the top plate and the shower plate)

In the present embodiment, a configuration in which a metal is inserted between the inner cylinder 130 and the shower plate 105 by changing the shape of a portion of components constituting the chamber 109 adopted. The head piece 133 (head piece+ring-shaped spacer) is electrically connected to the chamber 109 and grounded. In addition, the surface a on the inner side in contact with bulk plasma is coated with yttria and the neighborhood of a region H closer to the surface a of the top surface b and the bottom surface c is also coated with yttria.

In the present embodiment, a ring-shaped spacer portion integrally formed as a portion of the head piece 133 is arranged between the shower plate 105 and the inner cylinder 130 and therefore, the propagation of a micro wave from the shower plate 105 to the inner cylinder can be suppressed and a local discharge can be suppressed. Also, by making the inside diameter of the ring-shaped spacer portion included in the head piece 133 smaller than the inside diameter of the inner cylinder 130 smaller, a micro wave propagating up to the inner cylinder 130 by going through the sheath 200 can be reduced so that a local discharge can be suppressed more effectively. In addition, by integrally forming the ring-shaped spacer as a portion of the head piece, the number of components is reduced and the precision with which the inner cylinder, the shower plate, and the ring-shaped spacer are assembled can be improved.

As a result of applying the configuration shown in FIG. 4 to the plasma processing apparatus shown in FIG. 1 and applying the apparatus to plasma processing of semiconductor devices, the propagation of high frequency power from a shower plate into an inner cylinder made of a dielectric material such as quartz is blocked, generation of local plasma in a gap between the inner cylinder and a wall surface opposed to the inner cylinder is suppressed, and generation of metallic elements causing metallic contamination from the wall surface in the gap is suppressed and therefore, metallic contamination of a member to be processed during plasma processing can be reduced.

According to the present embodiment, as described above, a plasma processing apparatus capable of reducing metallic contamination of a member to be processed during plasma processing can be provided. In addition, a micro wave propagating up to the inner cylinder by going through the sheath can further be reduced by making the inside diameter D1 of the ring-shaped spacer smaller than the inside diameter D2 of the inner cylinder so that a local discharge can be suppressed more effectively. Also, by forming the ring-shaped spacer integrally with the head piece, the number of components is reduced and the precision with which the inner cylinder, the shower plate, and the ring-shaped spacer are assembled can be improved.

The present invention is not limited to the above embodiments and includes various modifications. For example, the above embodiments are described in detail to make it easier to understand the present invention and are not necessarily limited to embodiments including all described configurations. A portion of the configuration of some embodiment may be replaced by the configuration of another embodiment or the configuration of some embodiment may be added to the configuration of another embodiment. Also, an addition, deletion, or substitution of another configuration can be made to a portion of the configuration of each embodiment.

It should be further understood by those skilled in the art that although the foregoing description has been made on embodiments of the invention, the invention is not limited thereto and various changes and modifications may be made without departing from the spirit of the invention and the scope of the appended claims.

1. A plasma processing apparatus comprising:
a processing chamber;
a gas supply unit that supplies a process gas to the processing chamber;
an exhaust unit that reduces a pressure of the processing chamber;
a high frequency power supply that supplies high frequency power that generates plasma inside the processing chamber;
a stage electrode that is arranged in the processing chamber to mount a member to be processed on;
a high frequency bias power supply that applies a high frequency bias to accelerate ions incident on the member to be processed to the stage electrode;
a top plate that is installed in an upper portion of the processing chamber;
a shower plate that is installed below the top plate to supply the process gas into the processing chamber; and
an inner cylinder that is arranged below the shower plate to prevent a sidewall of the processing chamber from coming into direct contact with the plasma, wherein
the high frequency power to generate the plasma is introduced into the processing chamber via the top plate and the shower plate, and
a grounded spacer whose base material is a metal is installed between the shower plate and the inner cylinder.

2. The plasma processing apparatus according to claim 1, wherein
when an angular frequency to generate the plasma is ω, a magnetic permeability of the metal is μ, a conductivity is σ, and a thickness of the metal of the spacer inserted between the shower plate and the inner cylinder is t,
t≧(2/(ω·μ·σ))^{0.5}
holds.

3. The plasma processing apparatus according to claim 1, wherein
the spacer has a ring shape and an inside diameter of the spacer is smaller than the inside diameter of the inner cylinder.

4. The plasma processing apparatus according to claim 1, wherein
a surface of the spacer on a center side of the processing chamber is coated with a plasma resistant material.

5. The plasma processing apparatus according to claim 4, wherein
the plasma resistant material is yttria.

6. The plasma processing apparatus according to claim 1, wherein
the spacer is integrally formed as a portion of a head piece including a channel of the process gas.

7. The plasma processing apparatus according to claim 1, wherein
the inner cylinder and the shower plate are made of quartz or yttria.

8. A plasma processing apparatus comprising:
a grounded chamber;
a processing chamber that is arranged inside the chamber to process a member to be processed by using plasma;
a gas supply unit that supplies a process gas to the processing chamber;
an exhaust unit that reduces a pressure of the processing chamber;
a high frequency power supply that supplies high frequency power to generate the plasma;
a stage electrode that is arranged in the processing chamber to mount the member to be processed on;
a high frequency bias power supply that applies a high frequency bias to accelerate ions incident on the member to be processed to the stage electrode;
a shower plate that is installed in an upper portion of the processing chamber to supply the process gas into the processing chamber;
an inner cylinder that is arranged below the shower plate to prevent a sidewall of the chamber from coming into direct contact with the plasma;
a ground that is arranged to cover a portion of the inner cylinder via a gap and whose surface on a center side of the processing chamber is coated with a plasma resistant material; and
a spacer that is arranged between the shower plate and the inner cylinder by being grounded, whose surface on the center side of the processing chamber is coated with the plasma resistant material, and whose base material is a conductor.

9. The plasma processing apparatus according to claim 8, wherein
the ground is coated with the plasma resistant material also on a surface on a side of the inner cylinder.

10. The plasma processing apparatus according to claim 8, wherein
the spacer is grounded by being electrically connected to the chamber using a spiral seal.

11. The plasma processing apparatus according to claim 8, wherein
the spacer has a ring shape and an inside diameter of the spacer is smaller than the inside diameter of the inner cylinder.

12. The plasma processing apparatus according to claim 8, wherein
the plasma resistant material is yttria.

13. The plasma processing apparatus according to claim 8, wherein
the spacer is integrally formed as a portion of a head piece including a channel of the process gas.

14. The plasma processing apparatus according to claim 8, wherein
the inner cylinder and the shower plate are made of quartz or yttria.
